(19) United States
(12) Patent Application Publication
(10) Pub. No.: US 2026/0051455 A1
(43) Pub. Date: Feb. 19, 2026

(54) METHOD TO FABRICATE BLAZED GRATING USING SPACER AND ION BEAM ETCHING

(71) Applicant: Applied Materials, Inc., Santa Clara, CA (US)

(72) Inventors: Wenhui WANG, San Jose, CA (US); Zefang WANG, Santa Clara, CA (US); Lei JIANG, San Ramon, CA (US); Chan Juan XING, San Jose, CA (US); Yongan XU, Santa Clara, CA (US); Jinyu LU, Santa Clara, CA (US)

(21) Appl. No.: 19/291,984

(22) Filed: Aug. 6, 2025

Related U.S. Application Data
(60) Provisional application No. 63/684,133, filed on Aug. 16, 2024.

(51) Int. Cl. H01J 37/305; G02B 6/34

(52) U.S. Cl. CPC H01J 37/3056; G02B 6/34; H01J 2237/3151

(57) ABSTRACT

Aspects of the present disclosure includes methods of forming a waveguide. The method of forming a waveguide includes depositing a mandrel disposed over a substrate. Portions of the mandrel are etched to form a trench. A spacer material is deposited over the mandrel and the substrate. The spacer material is etched to form a spacer in the trench. The mandrel is etched using ion beam etching (IBE). The mandrel and the substrate are etched to form a blazed grating. The spacer is removed.

### CROSS-REFERENCE TO RELATED APPLICATIONS

This application claims priority to U.S. Provisional Patent Application No. 63/684,133, filed Aug. 16, 2024, which is herein incorporated by reference in its entirety.

### BACKGROUND

### Field

Embodiments of the present disclosure generally relate to optical waveguides. More specifically, embodiments described herein provide techniques for forming a waveguide having blazed gratings.

### Description of the Related Art

Virtual reality is generally considered to be a computer-generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

Blazed gratings are desired in AR waveguides for high diffraction efficiency into the targeted order. However, blazed gratings are difficult to manufacture using traditional patterning.

Accordingly, there is a need for improved systems and methods of forming blazed grating structures.

### SUMMARY

Embodiments of the present disclosure generally relate to optical waveguides. More specifically, embodiments described herein provide techniques for forming a waveguide having blazed gratings.

In one embodiment, a method of making a waveguide is disclosed. The method includes depositing a mandrel disposed over a substrate. Portions of the mandrel are etched to form a trench. A spacer material is deposited over the mandrel and the substrate. The spacer material is etched to form a spacer in the trench. The mandrel is etched using ion beam etching (IBE). The mandrel and the substrate are etched to form a blazed grating. The spacer is removed.

In yet another embodiment, a method of making a waveguide is disclosed. The method includes depositing a first mandrel over a substrate. The first mandrel is etched to form a trench. A spacer material is deposited over the substrate and the first mandrel. The spacer material is etched to form a spacer in the trench. A second mandrel material is deposited over the first mandrel, the substrate, and the spacer. The second mandrel material is etched. The first mandrel and the second mandrel material are etched using ion beam etching to form a second mandrel. The first mandrel, the second mandrel, and the substrate are etched to form a blazed grating. The spacer is removed

In yet another embodiment, a device is disclosed. The device includes a substrate having blazed gratings including a critical dimension (CD), a blazed surface, a sidewall, and a linewidth. The CD is defined by a width of an un-etched portion of the substrate. The CD has a width of less than about 10 nm. The blazed surface has a blazed angle defined between the blazed surface and the surface parallel to the substrate. The sidewall has a depth. The linewidth defines a distance between sidewalls of adjacent blazed gratings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1A is a perspective, frontal view of a waveguide, according to embodiments.

FIG. 1B is a schematic, cross-section view of the input coupling region at cross-section A-A, according to embodiments.

FIG. 2 is a flow diagram of a first method of forming a waveguide structure, according to embodiments.

FIGS. 3A-3F are schematic, cross-sectional views of a waveguide structure during the method of FIG. 2, according to embodiments.

FIG. 4 is a flow diagram of a first method of forming a waveguide structure, according to embodiments.

FIGS. 5A-5H are schematic, cross-sectional views of a waveguide structure during the method of FIG. 4, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to optical waveguides. More specifically, embodiments described herein provide techniques for forming a waveguide having blazed gratings.

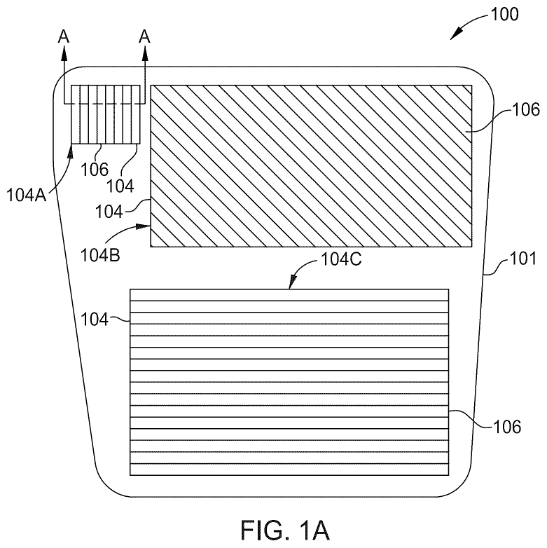

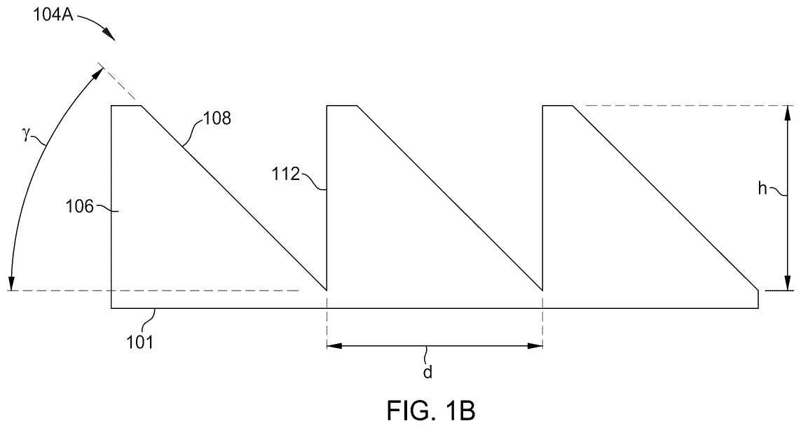

FIG. 1A is a front view of a waveguide combiner 100. It is to be understood that the waveguide combiner 100 described below is an exemplary waveguide combiner. The waveguide combiner 100 includes a substrate 101 and a plurality of optical devices 104. The plurality of optical devices 104 include an input coupling region 104A defined by a plurality of gratings 106, a waveguide region 104B, and an output coupling region 104C.

The input coupling region 104A receives incident beams of light (e.g., a light image) having an intensity from a micro-display. Each grating of the plurality of gratings 106 splits the incident beams into a plurality of modes. Zero-order mode (T₀) beams are refracted back or lost in the waveguide combiner 100. Positive first order mode (T₁) beams undergo total-internal-reflection (TIR) through the waveguide combiner 100 across the waveguide region 104B to the output coupling region 104C and output for display. Negative first-order mode (T₋₁) beams propagate in the waveguide combiner 100 a direction opposite the T₁ beams. Among the diffracted orders, only the T₁ beams output to display through output coupling region 104C, while other modes are lost due to different directionality. Therefore, it is beneficial to increase T₁ beam intensity and decrease other orders beam intensity for higher device optical efficiency. One approach to increase the intensity of T₁ beams and to reduce the intensity of the other order beams is to control the shape of each grating of the plurality of gratings 106. The plurality of gratings 106 may include blazed gratings. The blazed shape for each grating of the plurality of gratings 106 provides for increased optical efficiency.

The substrate 101 can be any suitable substrate, and can be either opaque or transparent to a chosen wavelength of light, depending for the use of the substrate 101 as a substrate for a waveguide. Substrate selection may include substrates of any suitable material, including, but not limited to, amorphous dielectrics, non-amorphous dielectrics, crystalline dielectrics, polymers, or combinations thereof. In some embodiments, the substrate 101 includes, but is not limited to, a silicon-containing material, a silicon and oxygen containing compound, a germanium-containing material, a indium and phosphide containing compound, a gallium and arsenic containing compound, a gallium and nitrogen containing compound, a carbon-containing material, a silicon and carbon containing compound, a silicon, carbon, and oxygen containing compound, a silicon and nitrogen containing compound, a silicon, oxygen, and nitrogen containing compound, a niobium and oxygen containing compound, and lithium, niobium, and oxygen containing compound, an aluminum and oxygen containing compound, a indium, tin, and oxygen containing compound, a titanium and oxygen containing compound, a lanthanum and oxygen containing compound, a gadolinium and oxygen containing compound, a zinc and oxygen containing compound, a yttrium and oxygen containing compound, a tungsten and oxygen containing compound, a potassium, and oxygen containing compound, a phosphorous and oxygen containing compound, a barium and oxygen containing compound, a sodium and oxygen containing compound, or combinations thereof. In other embodiments, which can be combined with other embodiments described herein, the substrate 101 includes an oxide including one or more of gadolinium, silicon, sodium, barium, potassium, tungsten, phosphorus, zinc, calcium, titanium, tantalum, niobium, lanthanum, zirconium, lithium, or yttrium containing-materials. Example materials of the substrate 101 include silicon (Si), silicon monoxide (SiO), silicon dioxide (SiO2), silicon carbide (SiC), fused silica, diamond, quartz germanium (Ge), silicon germanium (SiGe), indium phosphide (InP), gallium arsenide (GaAs), gallium nitride (GaN), sapphire, sapphire (Al2O3), lithium niobate (LiNbO3), indium tin oxide (ITO), lanthanum oxide (La2O3), gadolinium oxide (Gd2O5), zinc oxide (ZnO), yttrium oxide (Y2O3), tungsten oxide (WO3), titatium oxide (TiO2), zirconium oxide (ZrO3), sodium oxide (Na2O), niobium oxide (Nb2O5), barium oxide (BaO), potassium oxide (K2O), phosphorus pentoxide (P2O5), calcium oxide (CaO), or combinations thereof.

The optical devices 104 and the substrate 101 include a different material. The optical devices 104 includes, but is not limited to, one or more oxides, carbides, or nitrides of silicon, aluminum, zirconium, tin, tantalum, zirconium, barium, titanium, hafnium, lithium, lanthanum, cadmium, niobium, or combinations thereof. Example materials of the optical devices 104 include silicon carbide, silicon oxycarbide, titanium oxide, silicon oxide, vanadium oxide, aluminum oxide, aluminum-doped zinc oxide, indium tin oxide, tin oxide, zinc oxide, tantalum oxide, silicon nitride, zirconium oxide, niobium oxide, cadmium stannate, silicon oxynitride, barium titanate, diamond like carbon, hafnium oxide, lithium niobate, silicon carbon-nitride, silver, cadmium selenide, mercury telluride, zinc selenide, silver-indium-gallium-sulfur, silver-indium-sulfur, indium phosphide, gallium phosphide, lead sulfide, lead selenide, zinc sulfide, molybdenum sulfide, tungsten sulfide, or combinations thereof.

FIG. 1B is a schematic, cross-sectional view of the input coupling region 104A at cross-section A-A. In one embodiment, which can be combined with other embodiments described herein, the input coupling region 104A includes a plurality of blazed gratings 106. The methods 200 and 400 described herein form the plurality of blazed gratings 106. The waveguide combiner 100 includes blazed gratings 106. Each of the blazed grating 106 includes a blazed surface 108, sidewall 112, a depth h, and a linewidth d. The blazed surface has a blaze angle γ. The blaze angle γ is the angle between the blazed surface 108 and the surface parallel to the substrate 101 and the angle between the surface normal of the substrate 101 and facet normal f of the blazed surface 108. The depth h corresponds to the height of the sidewall 112 and the linewidth d corresponds to the distances between sidewalls 112 of adjacent blazed gratings 106.

In one embodiment, which may be combined with other embodiments, blaze angle γ of two or more blazed gratings 106 are different. In another embodiment, which may be combined with other embodiments, the blaze angle γ of two or more blazed gratings 106 are the same. In another embodiment, the depth h of two or more blazed gratings are different. In another embodiment, which may be combined with other embodiments, the depth h of two or more blazed gratings are the same. In one embodiment, which may be combined with other embodiments, the linewidths d of two or more blazed gratings 106 are different. In one embodiment, which may be combined with other embodiments, the linewidths of two or more blazed gratings 106 are the same.

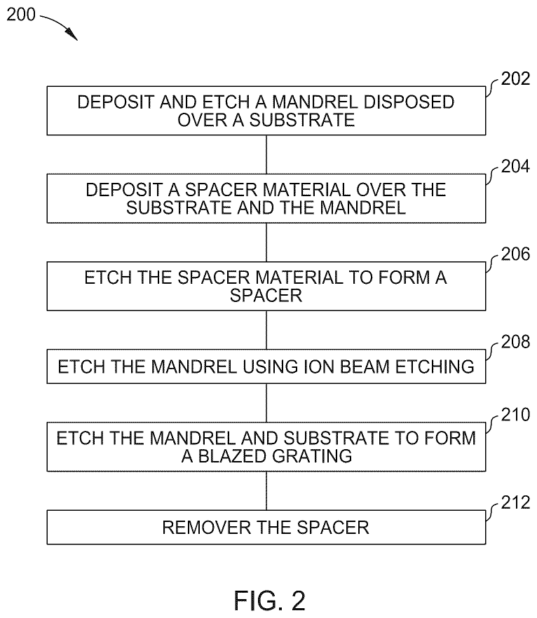

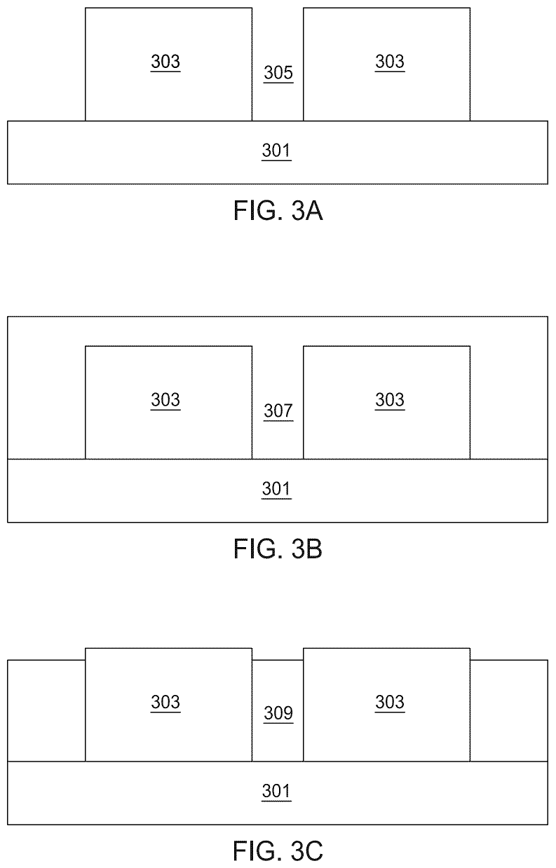

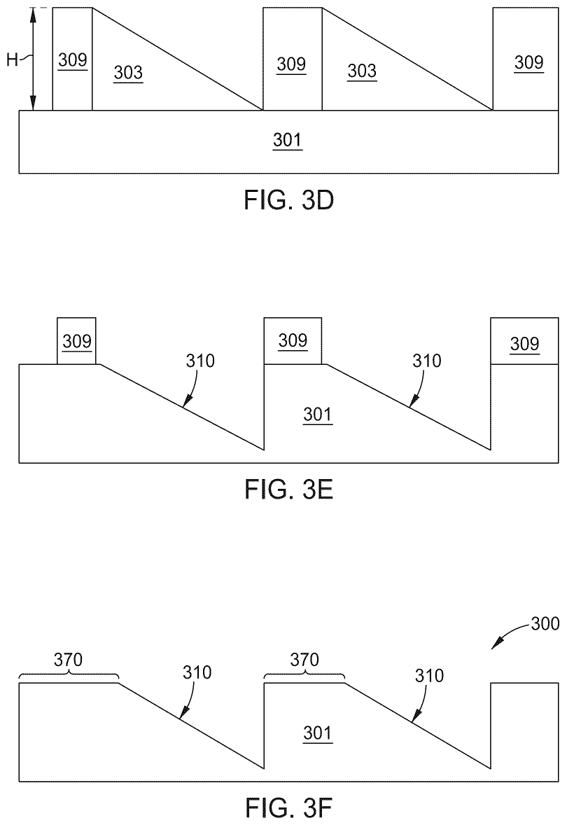

FIG. 2 is a flow diagram of a method 200 of forming a waveguide structure 300. FIGS. 3A-3F are schematic, cross-sectional views of a waveguide structure 300 during the method 200. The waveguide structure 300 corresponds to the input coupling region 104A of the waveguide combiner 100.

At operation 202, as shown in FIG. 3A, a mandrel 303 is deposited over a substrate 301 and etched to form a plurality of trenches 305. Generally, the mandrel 303 is a material layer that defines where a spacer (e.g., a spacer 309) is subsequently situated. The mandrel 303 is disposed over a substrate 301. Generally, when a second material or material layer is disposed over a first material or material layer, the second material or material layer is deposited on or over, either directly or indirectly, the first material or material layer. The substrate 301 corresponds to the substrate 101 of the waveguide combiner 100. The mandrel 303 includes an organic film (e.g., an advanced patterning film (APF) or an optical planarization layer (OPL), or a photoresist, or an amorphous silicon (α-Si)). The mandrel 303 is etched using a wet etch or a dry etch process. E.g., a photoresist is etched using a wet developer, an organic film is etched using an oxygen based dry etch, and an inorganic mandrel 303 (e.g., a silicon based material) is etched using a fluoride based dry etch.

At operation 204, as shown in FIG. 3B, a spacer material 307 is deposited over the substrate 301 and the mandrel 303. The spacer material 307 that is deposited in the trenches 305. The spacer material 307 includes silicon nitride (SiN), silicon oxide (SiOₓ), aluminum nitride (AlN), aluminum oxide (AlO), hafnium oxide (HfO), a combination thereof, or other suitable semiconductor material. In some embodiments, the spacer material 307 is deposited using an atomic layer deposition (ALD) process or a flowable chemical vapor deposition (FCVD) process.

At operation 206, as shown in FIG. 3C, the spacer material 307 is etched to form spacers 309 in the trenches 305. The removal of the spacer material 307 to form the spacers 309 exposes the mandrel 303. The spacer material 307 is etched using an isotropic etch process, a wet etch process, or a dry etch process. In some embodiments, in which the spacer material 307 is an oxide, a DHF material is used to perform the etch process. In other embodiments, in which the spacer material 307 is a nitride, a hot phosphor wet etch or an isotropic dry etch is used to perform the etch process. The spacers 309 have a height H greater than about 100 nm, such as about greater than 200 nm, such as about greater than 300 nm.

At operation 208, as shown in FIG. 3D, the mandrel 303 is etched. The mandrel 303 is etched using ion beam etching (IBE). The IBE is a directional etch having an etching angle that can be tuned. The IBE etch angle is defines by the blaze angle γ. The blaze angle is from about 1° to about 89°, such as about 10° to about 80°, such as about 20° to about 70°, such as about 30° to about 60°, such as about 40° to about 50°.

At operation 210, as shown in FIG. 3E, a mandrel 303 and the substrate 301 are etched to form a blazed grating 310. The etch process can be a dry etch, such as a chloride based etch process.

At operation 212, as shown in FIG. 3F, the spacer 209 is removed from a critical dimension (CD) 370. The spacer 309 is removed using a wet etch or a dry etch process. The wet etch includes a DHF or hot phosphor etch. The dry etch includes a fluoride or a chloride etch. The CD 370 is the width of the un-etched portion of the substrate 301. By using the IBE process to etch the mandrel 303, the width of the CD 370 is reduced, e.g., the CD 370 is less than about 10 nm, such as less than about 5 nm.

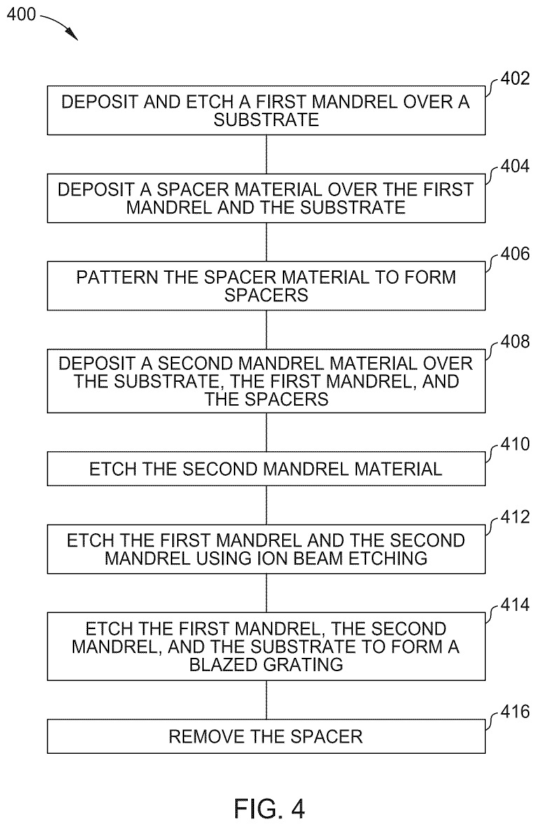

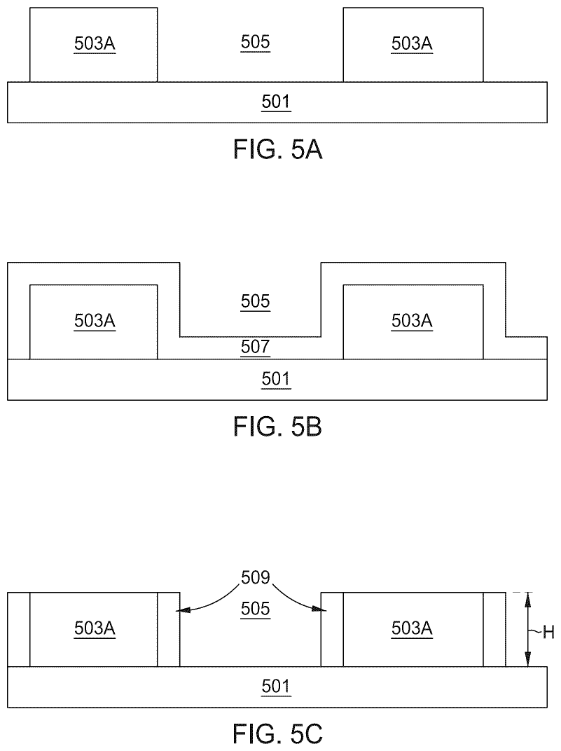

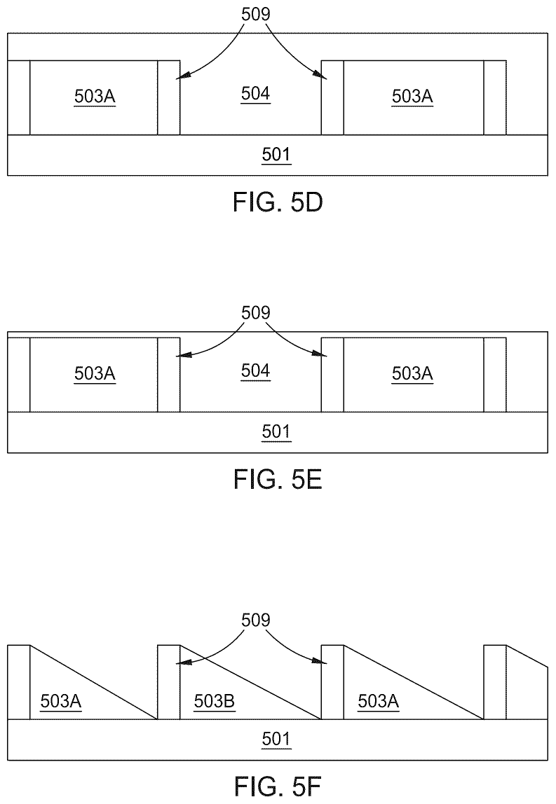

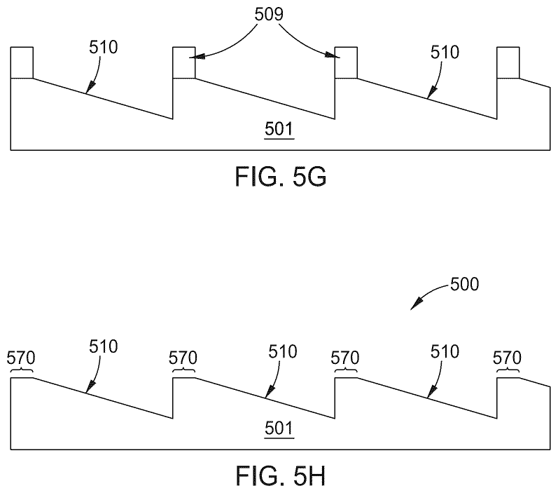

FIG. 4 is a flow diagram of a method 400 of forming a waveguide structure 500. FIGS. 5A-5H are schematic, cross-sectional views of a waveguide structure 500 during the method 400. The waveguide structure 500 corresponds to the input coupling region 104A of the waveguide combiner 100.

At operation 402, as shown in FIG. 5A, a first mandrel 503A is deposited over a substrate 501 and etched to form a plurality of trenches 505. The substrate 501 corresponds to the substrate 101 of the waveguide combiner 100. The first mandrel 503A includes an organic film (e.g., an advanced patterning film (APF) or an optical planarization layer (OPL), or a photoresist, or an amorphous silicon (α-Si)). The first mandrel 503A is etched using a wet etch or a dry etch process. E.g., a photoresist is etched using a wet developer, an organic film is etched using an oxygen based dry etch, and an inorganic mandrel 303 (e.g., a silicon based material) is etched using a fluoride based dry etch.

At operation 404, as shown in FIG. 5B, a spacer material 507 is deposited over the substrate 501 and the first mandrel 503A. The spacer material 507 includes silicon nitride (SiN), silicon oxide (SiOx), aluminum nitride (AlN), aluminum oxide (AlO), hafnium oxide (HfO), a combination thereof, or other suitable semiconductor material. In some embodiments, the spacer material 507 is deposited using an ALD process or a FCVD process.

At operation 406, as shown in FIG. 5C, the spacer material 507 is patterned to form spacers 509. The spacer material 507 is patterned using an isotropic etch process, a wet etch process, or a dry etch process. In some embodiments, in which the spacer material 507 is an oxide, a DHF material is used to perform the etch process. In other embodiments, in which the spacer material 507 is a nitride, a hot phosphor material or an isotropic dry etch is used as the dry etch material. The thickness of the spacer material 507 may be tailored to control the top critical dimension of the waveguide structure 500. In some embodiments, the spacers 509 have a height H greater than about 300 nm.

At operation 408, as shown in FIG. 5D, a second mandrel material 504 is deposited over the substrate 501, the first mandrel 503A, and the spacers 509. The second mandrel material 504 includes an organic film (e.g., an advanced patterning film (APF), a photoresist, or an optical planarization layer (OPL) or an amorphous silicon (α-Si)). In some embodiments, the second mandrel material 504 is deposited using a spin on process or a chemical vapor deposition (CVD) process. In some embodiments, the second mandrel material 504 may be the same material as the first mandrel 503A. In other embodiments, the second mandrel material 504 may be a different material from the first mandrel 503A.

At operation 410, as shown in FIG. 5E, a second mandrel material 504 is etched back. The second mandrel material 504 is etched using a wet etch or a dry etch process. E.g., a photoresist is etched using a wet developer, an organic film is etched using an oxygen based dry etch, and an inorganic mandrel 303 (e.g., a silicon based material) is etched using a fluoride based dry etch.

At operation 412, as shown in FIG. 5F, the first mandrel 503A and the second mandrel material 504 are etched. The first mandrel 503A is etched using ion beam etching. The ion beam etching (IBE) is a directional etch having an etching angle that can be tuned. The IBE etch angle is defines by the blaze angle γ. The blaze angle is from about 1° to about 89°, such as about 10° to about 80°, such as about 20° to about 70°, such as about 30° to about 60°, such as about 40° to about 50°. The IBE forms a blazed profile on both the first mandrel 503A and the second mandrel 503B.

At operation 414, as shown in FIG. 5G, a first mandrel 503A, second mandrel 503B, and the substrate 501 are etched to form a blazed grating 510. The etch process can be a dry etch or a wet etch process, such as a chloride based etch.

At operation 416, as shown in FIG. 5H, the spacer 209 is removed from a critical dimension 570. The spacer 309 is removed using a wet etch or a dry etch process. E.g., a DHF wet etch for an oxide, a dry fluoride etch for an oxide/silicon containing material, or a hot phosphor wet etch for silicon nitride. The CD 570 is the width of the un-etched portion of the substrate 501. By using the IBE process to etch the first mandrel 503A and the second mandrel 503B, the width of the CD 570 is reduced, e.g., the CD 570 is less than about 10 nm, such as less than about 5 nm.

In summary, the methods enable the formation of the blazed gratings on the waveguide structure without steps enables a reduction in the size of the CD. The reduction of the CD is facilitated, in part, by a reduced CD and increase in the height of the spacer. The reduced CD and increased height are enabled by the method using the IBE to etch the mandrels. The methods further enable increased process control, creating a repeatable process. Further, the process involve a single lithography step, thus simplifying the process.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A method of forming a waveguide, comprising:
depositing a mandrel over a substrate;
etching portions of the mandrel to form a trench;
depositing a spacer material over the mandrel and the substrate;
etching the spacer material to form a spacer in the trench;
etching the mandrel using ion beam etching (IBE);
etching the mandrel and the substrate to form a blazed grating; and
removing the spacer.

2. The method of claim 1, wherein the mandrel includes an organic film or an amorphous silicon (α-Si).

3. The method of claim 1, wherein the spacer material includes silicon nitride (SiN), silicon oxide (SiOₓ), aluminum nitride (AlN), aluminum oxide (AlO), hafnium oxide (HfO), or a combination thereof.

4. The method of claim 1, wherein the spacer material is deposited using an atomic layer deposition (ALD) process or a flowable chemical vapor deposition (FCVD) process.

5. The method of claim 1, wherein the IBE comprises a directional etch having a tunable etching angle, wherein the etching angle is defined a blaze angle, the blaze angle being from about 1° to about 89°.

6. The method of claim 1, wherein the spacer has a height greater than 300 nm.

7. The method of claim 1, wherein a critical dimension (CD) of the blazed grating has a width of less than about 10 nm.

8. A method of forming a waveguide, comprising:
depositing a first mandrel over a substrate;
etching the first mandrel to form a trench;
depositing a spacer material over the substrate and the first mandrel;
etching the spacer material to form a spacer in the trench;
depositing a second mandrel material over the first mandrel, the substrate, and the spacer;
etching on the second mandrel material;
etching the first mandrel and the second mandrel material using ion beam etching to form a second mandrel;
etching the first mandrel, the second mandrel, and the substrate to form a blazed grating; and
removing the spacer.

9. The method of claim 8, wherein the first mandrel and the second mandrel include an organic film or an amorphous silicon (α-Si).

10. The method of claim 9, wherein the first mandrel is a different material than the second mandrel.

11. The method of claim 9, wherein the first mandrel and the second mandrel are the same material.

12. The method of claim 8, wherein the spacer material includes silicon nitride (SiN), silicon oxide (SiOₓ), aluminum nitride (AlN), aluminum oxide (AlO), hafnium oxide (HfO), or a combination thereof.

13. The method of claim 8, wherein the spacer material is deposited using an atomic layer deposition (ALD) process or a flowable chemical vapor deposition process (FCVD) process.

14. The method of claim 8, wherein the spacer material is etched using an isotropic etch process, a wet etch process, or a dry etch process.

15. The method of claim 8, wherein the ion beam etching comprises a directional etch having a tunable etching angle, wherein the etching angle is defined a blaze angle, the blaze angle being from about 1° to about 89°.

16. The method of claim 8, wherein the spacer has a height greater than 300 nm.

17. The method of claim 8, wherein a critical dimension (CD) of the blazed grating has a width of less than about 10 nm.

18. A device, comprising:
a substrate having blazed gratings comprising:
a critical dimension (CD) defined by a width of an un-etched portion of the substrate, wherein the CD has a width of less than about 10 nm;
a blazed surface having a blazed angle defined between the blazed surface and the surface parallel to the substrate;
sidewall having a depth; and
a linewidth defining a distance between sidewalls of adjacent blazed gratings.

19. The device of claim 18, wherein the blazed grating is formed by:
depositing a mandrel disposed over a substrate;
etching portions of the mandrel to form a trench;
depositing a spacer material over the mandrel and the substrate;
etching the spacer material to form a spacer in the trench;
etching the mandrel using ion beam etching (IBE);
etching the mandrel and the substrate to form a blazed grating; and
removing the spacer.

20. The device of claim 18, wherein the blazed grating is formed by:
depositing a first mandrel over a substrate;
etching the first mandrel to form a trench;
depositing a spacer material over the substrate and the first mandrel;
etching the spacer material to form a spacer in the trench;
depositing a second mandrel material over the first mandrel, the substrate, and the spacer;
etching on the second mandrel material;
etching the first mandrel and the second mandrel material using ion beam etching to form a second mandrel;
etching the first mandrel, the second mandrel, and the substrate to form a blazed grating; and
removing the spacer.
